(19) United States
(12) Patent Application Publication
(10) Pub. No.: US 2026/0358721 A1
(43) Pub. Date: Nov. 12, 2026

(54) DOSE CONTROL SYSTEM

(71) Applicant: ASML Netherlands B.V., Veldhoven (NL)

(72) Inventors: Sean W. McGrogan, San Diego, CA (US); Oscar Franciscus Jozephus Noordman, Eindhoven (NL)

(21) Appl. No.: 19/125,037

(22) PCT Filed: Sep. 28, 2023
(86) PCT No.: PCT/EP2023/076982

§ 371 Date: Apr. 28, 2025

Related U.S. Application Data
(60) Provisional application No. 63/420,757, filed on Oct. 31, 2022.

(51) Int. Cl. G03F 7/00; G03F 7/20

(52) U.S. Cl. CPC G03F 7/70558; G03F 7/2004; G03F 7/70033; G03F 7/70041; G03F 7/705; G03F 7/70533

(57) ABSTRACT

A control apparatus includes: a power controller configured to control an amount of energy in an exposure beam; and a tracking module configured to: determine an amount of accumulated energy of a region that moves through the exposure beam while the region is in the exposure beam; predict whether the accumulated energy of the region will exceed a dose limit prior to leaving the exposure beam; and if the accumulated energy of the region is predicted to exceed the dose limit, provide a control input to the power controller.

### CROSS-REFERENCE TO RELATED APPLICATIONS

This application claims priority of U.S. application 63/420,757 which was filed on Oct. 31, 2022 and which is incorporated herein in its entirety by reference.

### TECHNICAL FIELD

This disclosure relates to a dose control system. The dose control system may be used with an optical system such as, for example, a pulsed laser, an extreme ultraviolet (EUV) light source that receives light from a light source, a deep ultraviolet (DUV) light source, an EUV lithography system, or a DUV lithography system.

### BACKGROUND

Extreme ultraviolet (“EUV”) light, for example, electromagnetic radiation having wavelengths of 100 nanometers (nm) or less (also sometimes referred to as soft x-rays), and including light at a wavelength of, for example, 20 nm or less, between 5 and 20 nm, or between 13 and 14 nm, may be used in photolithography processes to produce extremely small features in substrates, for example, silicon wafers, by initiating polymerization in a resist layer.

Methods to produce EUV light include, but are not necessarily limited to, converting a material that includes an element, for example, xenon, lithium, or tin, with an emission line in the EUV range in a plasma state. In one such method, often termed laser produced plasma (“LPP”), the required plasma may be produced by irradiating a target material, for example, in the form of a droplet, plate, tape, stream, or cluster of material, with an amplified light beam that may be referred to as a drive laser. For this process, the plasma is typically produced in a sealed vessel, for example, a vacuum chamber, and monitored using various types of metrology equipment.

### SUMMARY

In one aspect, a control apparatus includes: a power controller configured to control an amount of energy in an exposure beam; and a tracking module configured to: determine an amount of accumulated energy of a region that moves through the exposure beam while the region is in the exposure beam; predict whether the accumulated energy of the region will exceed a dose limit prior to leaving the exposure beam; and if the accumulated energy of the region is predicted to exceed the dose limit, provide a control input to the power controller.

Implementations may include one or more of the following features.

Providing the control input to the power controller may reduce the amount of energy in the exposure beam.

The power controller may include a proportional-integral controller, and the control input may include an input of the integrator. The input of the integrator may include an energy target and a control limit. When provided to the power controller, the control limit may reduce an amount of integral windup associated with the power controller.

The power controller may control the amount of energy in the exposure beam based on an energy target; and the control input may include an energy target, and, when the control input is provided to the power controller, the energy target may be reduced. The power controller may control the amount of energy in the exposure beam based on a proportional-integral controller; and the control input also may include a control limit, and, when the control limit is provided to the power controller, an amount of integral windup associated with the power controller may be reduced. When the control input is provided to the power controller, the integrator gain may be set to zero.

In some implementations, the region is a first region, and the tracking module is further configured to: determine an amount of accumulated energy of a second region that moves through the exposure beam while the second region is in the exposure beam, the second region being spatially distinct from the first region; predict whether the accumulated energy of the second region will exceed the dose limit prior to leaving the exposure beam; and if the accumulated energy of one or more of the first region and the second region is predicted to exceed the dose limit, provide a control input to the power controller.

The region may move through the exposure beam along a path from a first location at a first side of the exposure beam to a second location at a second side of the exposure beam, and to determine the amount of accumulated energy of the region while the region is in the exposure beam, the tracking module may be configured to: determine an amount of energy received at each location between the first location and a current location, the current location being on the path; and determine the accumulated energy of the region by summing all of the determined amounts of energy. To determine the amount of energy accumulated at a particular location on the path, the tracking module may be configured to: determine, for the particular location, a weighting factor based on a slit function that defines an energy distribution in the exposure beam; and determine the energy received at the particular location based on the weighting factor and a measured amount of energy. The measured amount of energy may be an amount of extreme ultraviolet (EUV) light provided to a lithography apparatus that forms the exposure beam.

The region may move through the exposure beam along a path from a first location at a first side of the exposure beam to a second location at a second side of the exposure beam, and to predict whether the accumulated energy of the region will exceed a dose limit prior to leaving the exposure beam, the tracking module may be configured to: determine if the accumulated energy of the region will exceed the dose limit if the region receives a target amount of energy at each remaining location on the path. The target amount of energy may vary over time such that the target amount of energy at each remaining location on the path is not constant. The target amount of energy at each remaining location may be determined based on an initial target energy and a weighting function that varies with the location. The accumulated energy may be determined based on the determined target amount of energy at each remaining location and a predefined gain factor. Reducing the predefined gain factor may reduce the determined amount of accumulated energy such that it is less likely that the accumulated energy will be predicted to exceed the dose limit, and increasing the predefined gain factor may increase the determined amount of accumulated energy such that it is more likely that the accumulated energy will be predicted to exceed the dose limit.

The dose limit may be a range of values, and, in these implementations, the accumulated energy of the region may be predicted to exceed the dose limit if the accumulated energy is outside of the range of values.

The power controller may be coupled to a light source that emits pulses of light, the exposure beam may be formed based on the pulses of light, and the control input may control an energy of pulses of light emitted by the light source to thereby control the amount of energy in the exposure beam. The exposure beam may be formed from extreme ultraviolet (EUV) light emitted by a plasma, and, in these implementations, the plasma may be generated by an interaction between the pulses of light emitted by the light source and a target material.

In another aspect, a system includes: an optical source configured to provide light to a lithography apparatus to form an exposure beam in the lithography apparatus; and a control apparatus including a power controller configured to control an amount of energy emitted by the optical source; and a tracking module configured to: determine an amount of accumulated energy of a region that moves through the exposure beam while the region is in the exposure beam; predict whether the accumulated energy of the region will exceed a dose limit prior to leaving the exposure beam; and if the accumulated energy of the region is predicted to exceed the dose limit, provide a control input to the power controller.

Implementations may include one or more of the following features.

The optical source may include an extreme ultraviolet (EUV) light source. The power controller may be configured to control the amount of energy emitted by the optical source by controlling a pulsed light source that provides pulses of light to a plasma formation region of the EUV light source. The power controller may be configured to control the amount of energy in the pulses of light provided to the plasma formation region of the EUV light source. The optical source also may include a pulsed light source that provides the pulses of light to a plasma formation region in the EUV light source. The optical source may include a carbon dioxide laser. The power controller may be further configured to control when the pulses are emitted from the pulsed light source.

The region may be a portion of a substrate that is configured to be received in the lithography apparatus.

The system also may include the lithography apparatus.

Implementations of any of the techniques described above may include a light source that includes a dose control system, a dose control system, a method, a process, a device, or an apparatus. The details of one or more implementations are set forth in the accompanying drawings and the description below. Other features will be apparent from the description and drawings, and from the claims.

### DRAWING DESCRIPTION

FIG. 1A is a block diagram of an example of an extreme ultraviolet (EUV) lithography system.

FIG. 1B is a block diagram of an example of a lithography apparatus.

FIG. 1C shows an example of a substrate.

FIG. 2 is a block diagram of an example of a control system.

FIG. 3 is a block diagram of an example of a dose control module and a power controller.

FIG. 4 is a flow chart of an example of a dose control process.

FIG. 5 is an example of an exposure beam.

FIG. 6 is an example of a weighting function.

FIGS. 7A-7G show examples of simulated data.

### DETAILED DESCRIPTION

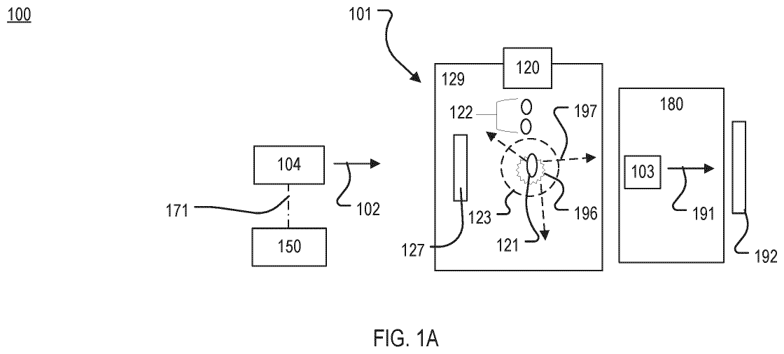

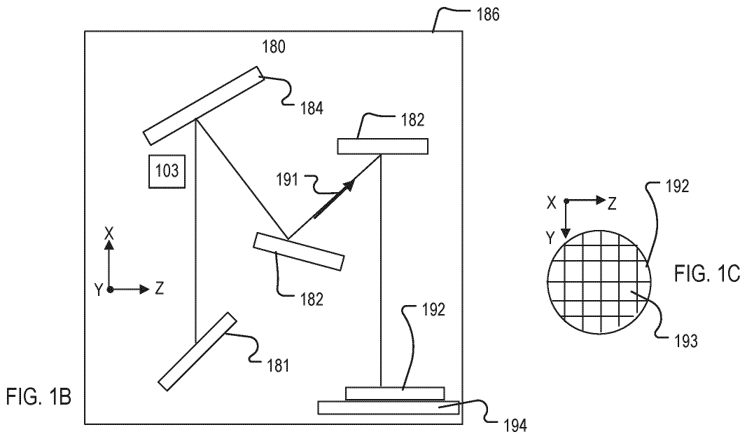

FIG. 1A is a block diagram of an extreme ultraviolet (EUV) lithography system 100 that includes an extreme ultraviolet (EUV) light source 101 and a scanner apparatus or lithography apparatus 180. FIG. 1B is a block diagram of the lithography apparatus 180. The EUV light source 101 provides EUV light 197 to the lithography apparatus 180. The scanner apparatus 180 produces an exposure beam 191 from the EUV light 197. The exposure beam 191 exposes a substrate 192 to form electronic features on a substrate 192 during a scanning or exposure pass. The lithography system 100 also includes a dose control system 150. As discussed in greater detail below, the dose control system 150 prevents or mitigates underdose errors and overdose errors. Dose is the amount of energy (for example, light) received at a portion 193 (FIG. 1B) of the substrate 192. The portion 193 is a region that has a finite area. Thus, dose is the amount of energy received at an area of the substrate. An underdose condition occurs when the amount of energy received at the portion 193 per unit area is less than a target dose or planned dose. An overdose condition occurs when the amount of energy received at the portion 193 per unit area exceeds the target dose or planned dose. An underdose condition may lead to improperly formed electronic features. Underdose conditions may be addressed though additional exposure or other repair techniques. However, an overdose condition may render a substrate 192 unusable. Because the consequence of an overdose condition is usually more severe than the consequence of an underdose condition, legacy dose control systems are optimized to prevent or mitigate overdose conditions but do not prevent underdose conditions.

On the other hand, the dose control system 150 prevents or mitigates overdose and underdose conditions by tracking the cumulative amount of energy received by a region on the substrate 192, predicting the total amount of energy that will be received at the region during the scanning pass, and initiating an intervention to correct the dose if the predicted total amount of energy received by the region over the scanning pass would result in a dose that exceeds the target dose. This allows the dose control system 150 to prevent overdose conditions while also preventing or reducing the occurrence of underdose conditions. Although underdose conditions do not necessarily render a substrate unusable, repairing the substrate 192 from underdose conditions consumes time and resources. Thus, the control system 150 improves the overall performance, reduces downtime, lowers costs, and increases the efficiency of the lithography system 100.

Moreover, the approach implemented by the control system 150 may result in increased throughput of the lithography system 100. Throughput may be measured as processed wafers per hour, for example. The approach described here may be used to decrease the rate of underdose faults at any given light source operating power setpoint. In other words, the approach can increase the power setpoint which gives rise to any given underdose fault rate. Hence, the light source's operating power setpoint can be increased, such that the resulting rate of underdose faults does not change relative to the prior art. An increase in operating power corresponds to an increase in wafer scan speed (for a given level of dose at the wafer, that is, energy per unit area), which is a direct increase in throughput.

An overview of the lithography system 100 is provided prior to discussing the control system 150 in greater detail.

The lithography system 100 includes an optical source 104. The optical source 104 produces a light beam 102 that propagates to a plasma formation region 123 in the EUV light source 101. The beam 102 may be a high-power (for example, tens or hundreds of Watts (W)) beam of light with a wavelength in the long-wave (LW) infrared region (for example, 9-12 microns (μm), 9-11 μm, 10-11 μm, 10.26 μm, 10.19 μm-10.26 μm or 10.59 μm). The optical source 104 may be, for example, a pulsed (for example, a Q-switched) or continuous-wave carbon dioxide (CO₂) laser. In the example shown, the system 100 includes an EUV sensor 103 that measures the amount of EUV light 197 output by the EUV light source 101 and provided to the lithography apparatus 180.

The EUV light source 101 includes a supply system 120 that produces a stream 122 of targets. The targets in the stream 122 travel in a vacuum chamber 129 toward the plasma formation region 123. In the example of FIG. 1A, a target 121 (which is part of the stream 122) is in the plasma formation region 123. Each target in the stream 122 includes target material, which is any material that emits EUV light when in a plasma state. For example, the target material may include water, tin, lithium, and/or xenon. Other materials may be used as the target material. For example, the element tin may be used as pure tin (Sn); as a tin compound, for example, SnBr₄, SnBr₂, SnH₄; as a tin alloy, for example, tin-gallium alloys, tin-indium alloys, tin-indium-gallium alloys, or any combination of these alloys. Moreover, the target material may be a target mixture that includes impurities that do not emit EUV light in a plasma state, such as non-target particles or inclusion particles. The non-target particles or inclusion particles may be, for example, particles of tin oxide (SnO₂) or particles of tungsten (W).

An interaction between the light beam 102 and the target 121 produces the plasma 196, which emits the EUV light 197. The EUV light 197 interacts with an optical element 127, which directs at least some of the EUV light 197 to the lithography apparatus 180. The optical element 127 may be a collector mirror that has an aperture through which the light beam 102 propagates and a curved reflective surface that faces the plasma formation region 123. The curved reflective surface reflects and focuses wavelengths in the EUV range toward the lithography apparatus 180.

In some implementations, the optical source 104 includes more than one optical source. In these implementations, the optical source 104 produces the light beam 102 and a second, distinct light beam that has different properties than the light beam 102. For example, the two distinct light beams may have different spectral properties (for example, different center wavelengths and/or different spectral bandwidths) and/or different average and/or peak power. In some implementations, the optical source 104 may include a second laser that emits a second light beam that has a wavelength of about 1 μm, such as, for example, a solid-state laser (for example, Nd:YAG laser or an erbium-doped fiber (Er:glass) laser). In other implementations, the optical source 104 includes a second source that is identical to the source that produces the high-powered light beam 102.

The second light beam may be used to condition the target 121 such that the production of EUV light is enhanced. For example, the interaction between the second light beam and a target in the stream 122 may change the shape, volume, and/or size of the distribution of the target material in the target in the stream 122 and/or may reduce the density gradient of the target material along the direction of propagation of the second light beam before the target interacts with the light beam 102. All of these changes enhance the ability of the target to absorb optical energy from the light beam 102 and increase the amount of target material converted into the plasma 196. The second light beam may be referred to as a pre-pulse beam or a preparation beam.

The system 100 also includes the control system 150. The control system 150 communicates with the optical source 104 via a communication link 171 (shown with a dashed-dot line style). The communication link 171 may be any type of medium that is capable of carrying information. For example, the data link may be an electrical cable, optical fiber, and/or a wireless connection. The control system 150 also may communicate with other components in the lithography system 100. For example, the control system 150 may send commands and/or receive data from the lithography apparatus 180 and/or the EUV light source 101.

Referring also to FIG. 1B, the lithography apparatus 180 includes an illuminator 181, reflective optical elements 182, a mask 184, all of which are in an enclosure 186. The EUV sensor 103 is between the mask 184 and the EUV light source 101. Thus, the EUV sensor 103 measures the amount of EUV light before the EUV light interacts with the mask 184. The illuminator 181 may include one or more reflective optical elements that shape the EUV light 197 into a spatial distribution of light that has a shape that depends on the arrangement of the illuminator 181. The spatial distribution may be, for example, a trapezoidal distribution of light. This distribution of light is referred to as a slit. The enclosure 186 is a housing, tank, or other structure that supports and encloses the illuminator 181, the reflective optical elements 182, and the mask 184. An evacuated space is maintained within the enclosure 186.

The EUV light 197 enters the enclosure 186, interacts with the illuminator 181, and is directed toward the mask 184. The mask 184 also may be referred to as a reticle or patterning device. The mask 184 includes a spatial pattern that represents the electronic features that are to be formed on a substrate 192. The EUV light 197 interacts with the mask 184. The interaction between the EUV light 197 and the mask 184 imparts the pattern of the mask 184 onto the EUV light 197 to form the exposure beam 191. The EUV light 197 is emitted in bursts, shots, or pulses, the duration and timing of which depend on the formation of the plasma 196 that emits the EUV light 197. Thus, the exposure beam 191 is a pulsed beam that delivers shots or bursts to the substrate 192.

The exposure beam 191 is directed to the substrate 192 by the optical elements 182. An interaction between the substrate 192 and the exposure beam 191 exposes the pattern of the mask 184 onto the substrate 192, thereby forming electronic features on the substrate 192. The dose delivered to each portion 193 on the substrate 192 depends on the size of the slit and the speed at which the slit is scanned relative to the substrate 192. The slit is scanned relative to the substrate 192 by moving the substrate 192 relative to the slit. In the system 100, the slit is scanned by moving the substrate 192 in the Y-Z plane while the slit remains stationary.

The substrate 192 may be a wafer of a semiconductor material, such as, for example, silicon. FIG. 1C shows a top view of the substrate 192 in the Y-Z plane. The substrate 192 includes a plurality of portions 193. The area of each portion 193 in the Y-Z plane is less than the area of the entire substrate 192 in the Y-Z plane. For simplicity, only one portion 193 is labeled in FIG. 1B. The portions 193 are depicted as being a rectilinear grid, but the portions 193 may take any form. Each portion 193 is any collection of spatial points on the substrate 192. For example, the portions 193 may include a sub-portion of one or more dies. Moreover, any or all of the portions 193 may be a single spatial point on the substrate 192.

The substrate 192 is mounted or placed on a moveable stage 194. The moveable stage 194 moves in the Y-Z plane relative to the exposure beam 191. In this way, each portion 193 on the substrate 192 is exposed by the exposure beam 191 and includes a spatial profile resulting from interaction with the mask 184. The moveable stage 194 also is able to move in the X direction.

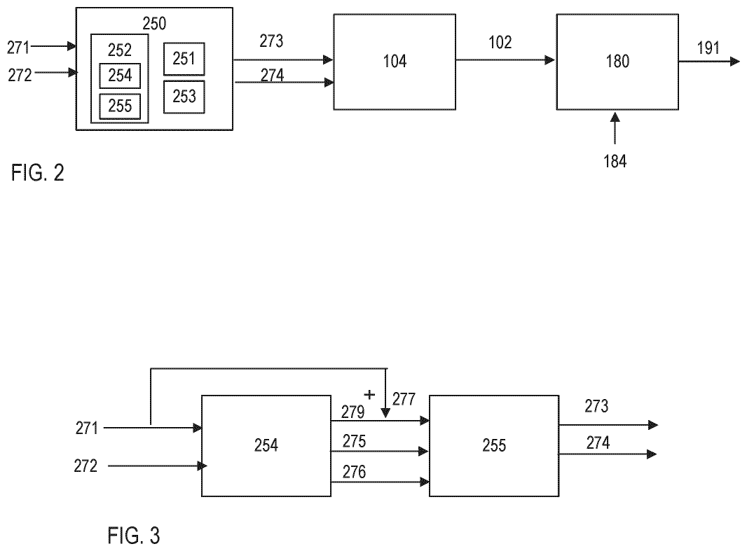

FIG. 2 is a block diagram of a control system 250 used with the optical source 104 and the lithography apparatus 180. The control system 250 controls the dose provided by the lithography apparatus 180. The control system 250 is an example of an implementation of the control system 150.

The control system 250 is an electronic control system and is implemented with an electronic processing module 251, an electronic storage 252, and an input/output (I/O) or communications interface 253. The electronic processing module 251 includes one or more processors suitable for the execution of a computer program such as a general or special purpose microprocessor, and any one or more processors of any kind of digital computer. Generally, an electronic processor receives instructions and data from a read-only memory, a random access memory (RAM), or both. The electronic processing module 251 may include any type of electronic processor. The electronic processor or processors of the electronic processing module 251 execute instructions and access data stored on the electronic storage 252. The electronic processor or processors are also capable of writing data to the electronic storage 252.

The electronic storage 252 may be volatile memory, such as RAM, and/or non-volatile memory. The I/O interface 253 is any kind of interface that allows the control system 250 to exchange data and signals with an operator, the optical source 104, the scanner apparatus 180, the EUV sensor 103, and/or an automated process running on another electronic device. For example, in implementations in which rules, instructions, and/or data stored on the electronic storage 252 may be modified, the modifications may be made through the I/O interface 253. The I/O interface 253 may include one or more of a visual display, a keyboard, and a communications interface, such as a parallel port, a Universal Serial Bus (USB) connection, and/or any type of network interface, such as, for example, Ethernet. The I/O interface 253 also may allow communication without physical contact through, for example, an IEEE 802.11, Bluetooth, or a near-field communication (NFC) connection.

The electronic storage 252 stores data and information that is used in the operation of the control system 250. For example, the electronic storage 252 may store a value that represents a target dose or planned dose to be provided to each portion 193 in units of energy per unit area (for example, millijoules (mJ) per square centimeter (cm²)). The electronic storage 252 also may include specification information related to the optical source 104. The specification information may include, for example, target energy, wavelength, and/or spectral bandwidth of pulses in the light beam 102 produced by the optical source 104. The specification information also may include parameters and data related to the lithography apparatus 180. For example, the specification information may include information that describes the shape of the slit and/or parameters that describe the motion of the slit relative to the substrate 192. The electronic storage 252 also may store information received from the optical lithography system 100, the scanner apparatus 180, and/or the optical source 104 for later analysis.

Furthermore, the electronic storage 252 stores instructions (for example, in the form of one or more computer programs or software) that cause the control system 250 to interact with other components and subsystems in the optical lithography system 100 and/or execute processes related to the control of the system 100. For example, the electronic storage 252 stores executable instructions that implement a dose control module 254 and a power controller 255.

FIG. 3 is a block diagram of the dose control module 254 and the power controller 255. The power controller 255 generates control commands that control the optical source 104. The control commands include an optical source gain control command 273 and a timing command 274. The optical source gain control command 273 controls the intensity of the optical pulses in the light beam 102 that is emitted from the optical source 104. For example, the optical source gain control command 273 may control the temporal duration of the pulses in the beam 102, the peak energy of the pulses in the beam 102, and/or the shape of the pulses in the beam 102.

The timing command 274 controls when the pulses are emitted from the optical source 104. The intensity and timing of the pulses in the beam 102 affect the amount of EUV light 197 produced by the source 104. For example, if the amount of EUV energy in the pulses of EUV light 197 is too great even when the optical source gain control command 273 is at its minimum, the power controller 255 may use the timing command 274 to intentionally reduce the production of the EUV light 197 by commanding the optical source 104 to delay emission of one or more pulses of light such that the light beam 102 does not interact with as many targets in the stream 122. Thus, by controlling the content of the commands 273 and 274, the amount of EUV light 197 is also controlled.

The power controller 255 may implement a proportional-integral (PI) control scheme to produce the optical source gain control command 273 and the timing command 274. Equations (1a) and (1b) show representations of the PI control scheme:

u(t)=P+I+G_{S0} Equation (1a),

where u is the control variable, P is a proportional term, and I is an integral term. The proportional term P and the integral term I in Equation (1a) also may be expressed as:

$$u ( t ) = {K}_{p} e ( t ) + {K}_{i} {\int }_{0}^{t} e ( τ ) d τ + {G}_{S 0} , \qquad Equation ( lb )$$

where u(t) is the control variable provided to the optical source 104 in the source gain control command 273, Kp is a proportional constant coefficient, e(t) is an error term, Ki is an integral constant coefficient or the integral gain, and where G_{S0} is an initial condition of the dose controller 254.

In implementations in which the source controller 255 implements a PI control scheme (such as this example), G_{S0} is the value of the gain control command 273 if the P and I terms are zero (0). The error term (e) is the difference between a set point (the target EUV power) and a measured process variable (the measured or actual EUV power). The proportional term (P) is proportional to the current error value (e). The integral shown in Equation (1b) accounts for the past values of the error term and integrates them over time to produce the integral term (I). For example, if there is a residual error that remains after the power controller 255 provides the optical source gain control command 273 to the optical source 104, the integral term (I) seeks to eliminate this residual error by adding a control effect due to the cumulative value of the error. When the error is eliminated, the integral term (I) does not increase.

On the other hand, if the residual error is large and/or persists over time, the integral term (I) may continue to increase in amplitude (either positive or negative). This large integral term (I) value may drive the value of the control variable (u) (the gain control command 273) that causes the controlled physical system (the optical source 104 in this example) to saturate. In other words, the control variable (u) may grow so large that the source 104 cannot be driven to meet the output requested by the power controller 255. When the integral term (I) is in this condition, the controller 250 has integral windup. Equations (2) and (3) provide example expressions related to integral windup:

uₘₐₓ=0+I_{edge}+G_{S0} Equation (2),

where I_{edge} is the value of the integral term (I) when the proportional term (P) is zero (0) and the control variable u is at its maximum allowable value. For example, the value of the control variable (u) (the gain control command 273) may be between 0 and 1, where u=1 corresponds to a condition under which the source 104 is driven at its maximum power. In other words, uₘₐₓ is the value of the source gain control command 273 above which no additional output power can be obtained from the source 104. The determination of I_{edge} depends on the configuration of the controller 255, but in some implementations, I_{edge} is determined from Equation (3):

I_{edge}=1−Gₛ₀ Equation (3),

where G_{S0} is an initial condition of the dose controller 254. The maximum value of the integral term (Iₘₐₓ) is provided by:

Iₘₐₓ=I_{edge}+WUₘₐₓ Equation (4),

where WUₘₐₓ is the maximum amount of windup.

One approach to addressing integral windup is to place a limit on the value of the integral term (I) and keep that limit in place during the operation of the system 100. For example, one approach is to plug in a value of 0 (or any other finite number) for WUₘₐₓ into Equation (4). However, limiting the integral term (I) in this manner may cause the control system 250 to prematurely and/or unnecessarily reduce an energy target 277 that is provided to the power controller 255, thereby reducing the intensity of the pulses in the light beam 102 and the amount of EUV light 197. In other words, such an approach may increase the chances of an underdose condition.

On the other hand, the dose control module 254 acts on the power controller 255 to address integral windup during the scanning process by resetting the windup (WU) term rather than limiting the integral term. Resetting the windup (WU) term has the effect of removing or reducing integrator windup and the allows the controller 255 to begin tracking a reduced set point right away. This temporary restriction and reset allows the dose control module 254 to avoid or reduce underdose conditions and overdose conditions.

In greater detail, the dose control module 254 tracks the EUV energy accumulated at one or more tracked regions on the substrate 192 during an exposure, predicts the total amount of EUV energy that will be accumulated at the one or more regions during the entire scan, and then determines whether to intervene to reset the windup (WU) to a new value.

The dose control module 254 receives a input set point 271 and an input measurement 272 as inputs. The input set point 271 may be a target amount of EUV energy. The input measurement 272 may be a measured amount of EUV provided by the EUV sensor 103. The dose control module 254 uses the input set point 271 and the input measurement 272 to determine a control limit 275 and an energy target modification 279. The control limit 275 is a value for the windup term (WU). The energy target 277 is a set point or target for the EUV energy in a pulse of light in the light beam 102, and is the energy target used by the power controller 255. The dose control module 254 also outputs a reset command 276 that indicates whether or not the windup term (WU) should be set to a known value (for example, the control limit 275) to remove the effect of integral windup.

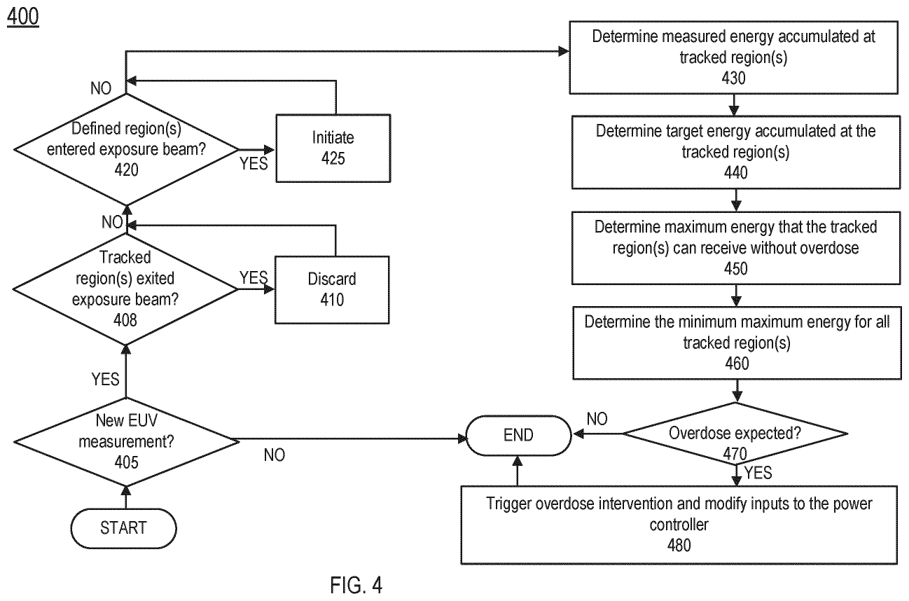

FIG. 4 is a flow chart of a process 400. The process 400 is an example of a dose control process implemented by the dose control module 254. The process 400 may be implemented as machine-executable instructions that are stored on the electronic storage 252 as the dose control module 254.

The process 400 begins when a new EUV measurement is acquired (405) and may be performed each time an EUV measurement is acquired.

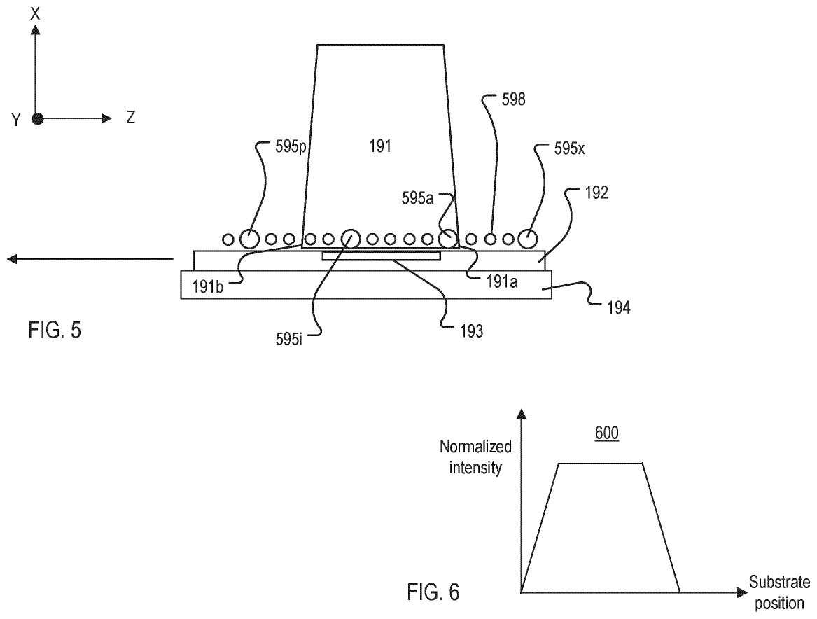

One or more candidate regions for tracking are defined. The candidate regions are regions on the substrate 192 that may be tracked as they move through the exposure beam 191 during an exposure. An example of the candidate regions is discussed with respect to FIG. 5, which shows the substrate 192 at an instant in time. The exposure beam 191 propagates in the −X direction and the substrate 192 extends in the Y-Z plane. The exposure beam 191 is depicted with a trapezoidal shape to represent that, in this example, the intensity distribution of the light within the exposure beam 191 is trapezoidal as a function of position in the Z direction.

The substrate 192 is mounted on the moveable stage 194, which, during exposure or a scan, moves the substrate 192 in the −Z direction. An exposure field is the physical area of the substrate 192 that will ultimately become (after more processing steps) one unit of the device being created (e.g. a microchip). Between two exposures or between two scans, the moveable stage 194 may move in the +/−Y direction so that additional parts of the substrate 192 can be exposed in a later scan. The substrate 192 includes a plurality of portions 193, only one of which is labeled in FIG. 5. The substrate 192 has a larger extent in the Y-Z plane than the exposure beam 191.

The circles above the substrate 192 represent regions on the substrate 192, with the smaller circles (for example, 598) representing regions that are not tracked and the larger circles (for example, 595x) representing regions that are candidates for tracking. In the example shown, each of the candidate regions 595p, 595i, 595a, 595x is smaller than the portion 193. In the example of FIG. 5, one tracked region 595i is within the boundary of what is depicted as the portion 193. Other implementations are possible. For example, the portion 193 may include two candidate regions or more than two candidate regions.

Any number of candidate tracked regions may be defined. For example, one tracked region, 10 tracked regions, 20 tracked regions, or 100 tracked regions may be defined. Using more tracked regions may improve the accuracy of the process 400 but increases computational demands. In implementations in which more than one tracked region is defined, a tracking spacing that indicates the spatial extent between adjacent tracked regions also may be defined.

The candidate tracking regions are analyzed to determine if any of the candidate regions have exited the exposure beam 191 since the last time an EUV measurement was processed (408). Candidate regions that have exited the exposure beam 191 are discarded and are not tracked. In the example of FIG. 5, the region 595p has exited the exposure beam 191 and is discarded. After discarding candidate regions that have exited the exposure beam 191, the process 400 advances to (420).

The process 400 determines whether any of the candidate tracking regions have entered the exposure beam 191 since the last time an EUV measurement was processed (420). In the example of FIG. 5, the candidate regions 595i and 595a are in the exposure beam 191. Candidate tracking regions that are in newly in the exposure beam 191 since the last time an EUV measurement was processed are initiated for tracking (425) by determining an initial position and initial energy at each tracked region. The initial energy is the amount of EUV energy received at a tracked region at the time that the region is initiated. The current position of each tracked region relative to the exposure beam 191 is determined. The exposure beam 191 extends in the −Z direction from a first edge 191a to a second edge 191b. A complete scan of a tracked region includes the light exposure that occurs from the time at which the tracked region enters the exposure beam 191 at the first edge 191a and the time at which the tracked region exits the exposure beam 191 at the second edge 191b. The current position of the tracked region is relative to the first edge 191a of the exposure beam 191.

Candidate regions that have not yet entered the exposure beam 191 (such as the region 595x) become tracked regions when the region enters the exposure beam 191 at the first edge 191a.

The tracked region is exposed by the exposure beam 191 for a period of time that depends on the speed of the stage 194 and the width of the exposure beam 191 in the direction of motion of the stage 194. The intensity of the exposure beam 191 as a function of spatial position in the direction of motion of the stage 194 (or time since entering the exposure beam 191) at the substrate 192 depends on the shape of the slit and/or settings of various components in the lithography apparatus 180. Due to these various factors, the intensity of the exposure beam 191 is not necessarily constant in the direction of motion of the stage 194. For example, the intensity of the exposure beam 191 along the direction of motion of the stage 194 (or time since entering the exposure beam 191) may be trapezoidal, a step function, or triangular. The weighting function for the slit describes the intensity of the exposure beam 191 along the direction of motion of the stage 194 (or time since a tracked region entered the exposure beam 191) at the substrate 192. FIG. 6 is an example of a weighting function 600. The weighting function 600 is normalized intensity of the exposure beam 191 as a function of position or time at the substrate 192.

Thus, the amount of energy received by the one or more tracked regions at any particular time during scanning is variable. Moreover, the amount of energy in the pulses of the light beam 102 may vary, and this energy variation also contributes to variation in the amount of energy received by each tracked region at a particular time.

The measured amount of energy accumulated at the tracked regions is determined (430). The measured amount of energy (EtrM(z)) per unit area received at a tracked region when it is at position z is shown in Equation (5):

EtrM(z)=ElbM(z)*W(z) Equation (5),

where z is the current spatial position of the tracked region relative to the edge 191a; ElbM(z) is the measured energy contained in the EUV light beam 197, provided by the EUV sensor 103 at a time that corresponds to the tracked region being at the position z; and W(z) is the value of the weighting function at the position z. The accumulated measured energy (EtrAccM(z)) per unit area received at the tracked region when the tracked region is in the position z is given by Equation (6):

$$E t r A c c M ( z ) = {\sum }_{p = 0}^{z} E t r M ( p ) , \qquad Equation ( 6 )$$

where p is an integer value that indexes the positions that the tracked region has passed through since entering the exposure beam 191 at z=0, where z=0 is the edge 191a of the exposure beam 191. Equations (5) and (6) may be expressed in time instead of space.

Analogous terms can be defined for the energy targets. The target energy accumulated at the tracked region(s) is determined (440). The target amount of energy (EtrT(z)) per unit area received at a tracked region when it is at position z is shown in Equation (5b):

EtrT(z)=ElbT(z)*W(z) Equation (5b),

where ElbT(z) is the target energy contained in the EUV light beam 197 at a time that corresponds to the tracked region being at the position z. Note that the target amount of energy (EtrT(z)) per unit area is not necessarily constant. Similarly, the accumulated target energy (EtrAccT(z)) per unit area received at the tracking region when the tracked region is in the position z is given by Equation (6b):

$$E t r A c c T ( z ) = {\sum }_{p = 0}^{z} E t r T ( p ) . \qquad Equation ( 6 b )$$

The variables z and p in Equations 5b and 6b are defined as noted above for Equations (5) and 6.

Overdose prevention is performed by determining, for each tracked region, an amount of additional energy (Elb_{MaxAdd}) that may be received without overdose occurring (450). For any tracked region, Elb_{MaxAdd} is the amount of EUV light beam 197 energy which would cause that tracked region to experience an overdose fault, if the next value of the measured energy in the EUV light beam 197 (ElbM) was equal to (ElbT+Elb_{MaxAdd}), and all subsequent values of the measured energy in the EUV light beam 197 (ElbM) were equal to a predicted amount of EUV light beam 197 energy.

The process 400 has a target dose, which is the target or goal amount of EUV energy per unit area that the tracked region should receive during the entire scan. This is the accumulated target energy (EtrAccT(z)) per unit area when z is equal to the position of the tracked region when the tracked region exits the exposure beam 191. The tracked region experiences an overdose fault when the dose received at the tracked region exceeds the target dose by an overdose limit (ODL). The tracked region experiences an underdose fault when the dose received at the tracked region over the entire scan is less that the target dose by an underdose limit (UDL). The overdose limit and the underdose limit may be expressed as percentages or as numerical values. For example, the tracked region may be considered to not experience an underdose or an overdose fault if the dose received at the tracked region during the scan is within +/−1% of the target dose.

To perform the overdose prevention, the amount of additional energy (Elb_{MaxAdd}) is estimated. If there is more than one tracked region, the amount of additional energy (Elb_{MaxAdd}) is determined for each tracked region.

The maximum amount of additional energy (Elb_{MaxAdd}) may be estimated as follows:

$$E l {b}_{Ma xAdd} = \frac{[ O D L * ( E t r A c c T ( z ) + E t r A c c {T}_{r e m} ) - ( E t r A c c M ( z ) + E t r A c c {M}_{r e m} ) ]}{W ( z )} , \qquad Equation ( 7 )$$

where z is the current position of the tracked region, ODL is the overdose limit discussed above (for example, if it is desired to prevent overdose from exceeding 0.8%, then ODL can be set to 1.008), EtrAccT(z) is the target energy accumulated by the tracked region so far (as determined from Equation (6b) above), EtrAccTᵣₑₘ is a prediction of the remaining target energy that will be accumulated by the tracked region between the current time and exiting the exposure beam 191 at the second edge 191b, EtrAccM(z) is the measured energy accumulated by the tracked region so far (as determined from Equation (6) above), and EtrAccMᵣₑₘ is a prediction of the remaining measured energy that will be accumulated by the tracked region between the current time and exiting the exposure beam 191 at the second edge 191b. EtrAccTᵣₑₘ can be estimated by multiplying the current energy target (ElbT(z)) by the sum of the weighting values W that the tracked region will experience between the current time (when it is located at position z) and the moment the tracked region has exited the exposure beam 191 (that is, when the tracked region is at position z_exit, which is the second edge 191b). That is,

$$E t r A c c {T}_{r e m} = E l b T ( z ) * {\sum }_{p = z}^{{z}_{-} e x i t} W ( p ) . \qquad Equation ( 8 )$$

If the upcoming values of the energy target (ElbT) are available, they can be utilized rather than assuming ElbT will stay constant at its current value (ElbT(z)). When upcoming values of energy target (ElbT) are available, Equation (8) becomes a dot product.

The amount of accumulated energy that is predicted to be measured at the tracked region for the remainder of the scan (EtrAccMᵣₑₘ) is determined by Equation (9):

EtrAccMᵣₑₘ=PessimismFactor*EtrAccTᵣₑₘ Equation (9),

where PessimismFactor is a number between 0 and 1. PessimismFactor affects how optimistic or pessimistic the algorithm acts. If PessimismFactor is increased, Elb_{MaxAdd} decreases; making it more likely that the process 400 will determine that an overdose will occur at (450). Decreasing the PessimismFactor makes it less likely that that the process 400 will determine that an overdose will occur at (450). The value of the PessimismFactor is chosen to provide a balance between intervening late (resulting in larger amounts and/or periods of energy reduction in order to prevent overdose) versus intervening so early that avoidable underdose faults are not avoided.
The maximum additional energy (Elb_{MaxAdd}) for each tracked region is determined.

After determining the maximum additional energy (Elb_{MaxAdd}) for each tracked region, the minimum value of all of the determined maximum additional energy (Elb_{MaxAdd}) values is determined (460). If the minimum value of all of the maximum additional energy (Elb_{MaxAdd}) values is equal to or less than zero (0), then at least one tracked region has a maximum additional energy (Elb_{MaxAdd}) that is less than or equal to zero (0), indicating that an overdose condition is expected to occur for one or more tracked regions (470). If an overdose condition is expected to occur, the overdose intervention is triggered and inputs to the power controller 255 are modified (480) to prevent an overdose fault from occurring.

When the intervention is triggered, the reset command 276 is set to a value or setting (for example HIGH or 1) to indicate that a temporary intervention is occurring, the windup (WU) term is set to a reset value, the control limit 275 is set to a temporary limit value, and the energy target 277 provided to the power controller 255 is temporarily reduced to avoid an over-exposure condition. In other words, modified inputs are provided to the power controller 255. Equations (10) and (11) are examples of equations that implement the intervention:

WU=newWU Equation (10),

where WU is the windup limit and newWU is a numerical value that represents the amount of acceptable windup limit for the application. The value of newWU may be zero (0), which removes the integral windup. The value of newWU may be set to a value other than zero (0), for example, to reduce but not entirely remove the integral windup. The integral term (I) is limited as shown in Equation (11):

I=min(I,Iₘₐₓ) Equation (11),

where Iₘₐₓ is determined from Equation (4) using the value of WU determined in Equation (10). For example, if the value of WU is set to 0, then, based on Equation (2), Imax is equal to Iedge.

The value of the Iₘₐₓ term determined in Equation (4) is provided to the power controller 255 as the control limit 275. In other words, the value of the integral term (I) in the power controller 255 is reduced or stepped down quickly because the windup has been removed or reduced.

The energy target 277 used by the power controller 255 is also reduced. For example, the energy target 277 used by the power controller 255 may be reduced to the sum of the value of the input set point 271 and Elb_{MaxAdd}.

As noted above, overdose intervention is triggered by the minimum maximum additional energy (Elb_{MaxAdd}) being less than or equal to zero.

In this way, the integral windup is removed (or reduced, depending on the value of newWU) and the energy target 277 used by the power controller 255 is reduced. By removing or reducing the integrator windup, the power controller 255 will begin tracking the new, lower energy target 277 right away, the source 104 will be controlled in a manner that reduces the power of the pulses in the beam 102 such that less EUV light 197 is produced, and the overdose condition is avoided. After providing the control limit 275 to the power controller 255, the process 400 ends or returns to (410).

If all of the tracked regions have maximum additional energy (Elb_{MaxAdd}) that is greater than zero (0), then no overdose is expected, the overdose prevention intervention is not triggered, and the process 400 ends at (470) or returns to (410) to continue monitoring.

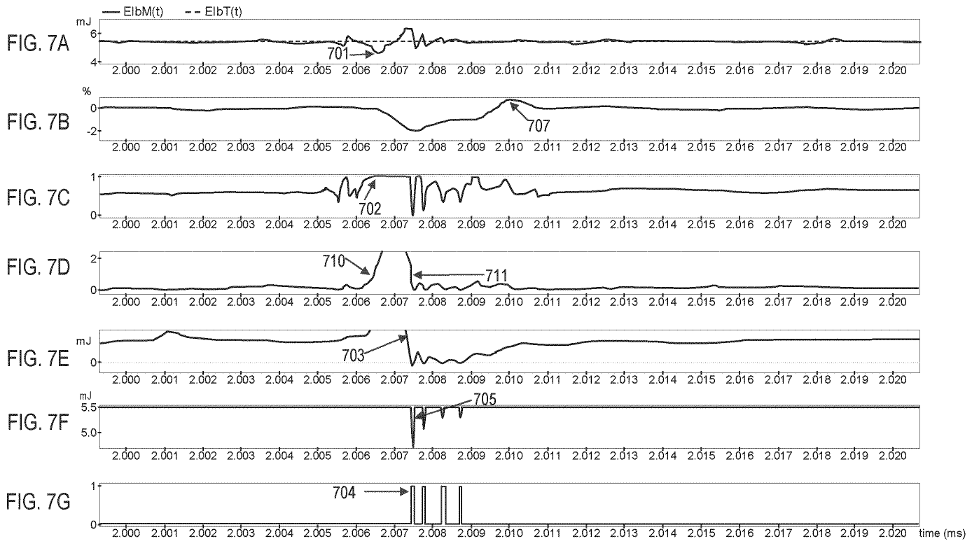

FIGS. 7A-7G show simulated data under conditions in which dropouts or reductions in EUV energy occurred. To generate the data shown in FIGS. 7A-7G, an ODL of 1.007 was used. That is, the overdose limit was 0.7%.

All of FIGS. 7A-7G have the same time scale (in milliseconds or ms) on the x-axis. FIG. 7A shows measured EUV (solid line) and target EUV (dashed line) in millijoules (mJ) as a function of time. FIG. 7B shows dose error of a region that just exited the exposure beam 191 in percentage as a function of time. In this example, the dose error is the percentage difference between the target dose and the actual dose. FIG. 7C shows the source gain control command 273 as a function of time. In the example of FIG. 7C, the gain control command 273 has a value between 0 and 1. FIG. 7D shows the integrator value (I) of Equation (1a). FIG. 7E shows the minimum of all values of Elb_{MaxAdd} (the maximum additional energy that a tracked region may receive before overdose occurs) in millijoules (mJ) as a function of time. FIG. 7F shows the value of the energy target 277 used by the power controller 255 as a function of time. In this example, the energy target 277 had a maximum value of about 5.5. FIG. 7G shows the value of the reset command 276 as a function of time. When the reset command 276 is HIGH (1 in this example), the intervention discussed in (480) of the process 400 (FIG. 4) is triggered.

As shown in FIG. 7A, a drop in measured EUV (labeled 701) was simulated between 2.006 ms and 2.007 ms. In response, the integrator winds up, and the integrator value (I) increases (as shown at the point labeled 710 in FIG. 7D). The value of the source gain control command 273 increases to its upper limit shortly after the time 2.006 ms, as shown in FIG. 7C at the point labeled 702. Additionally, and as shown in FIG. 7E, the minimum value of Elb_{MaxAdd} approaches zero (0) at the point labeled 703, which is after the time 2.006 ms. Shortly thereafter, the minimum value of Elb_{MaxAdd} falls below 0. As discussed above, the minimum value of Elb_{MaxAdd} falling below 0 is an indication that an overdose is likely to occur. In response, and as shown in FIG. 7G, the intervention discussed with respect to (480) of process 400 is triggered at the point labeled 704 which coincides with the minimum value of Elb_{MaxAdd} crossing zero (0). As shown in FIG. 7F, at the point labeled 705, the energy target 277 is reduced in response, and, as shown in FIG. 7C, the source gain command 273 is no longer at its maximum value. Moreover, and as shown in FIG. 7D at the point labeled 711, the integrator value (I) also decreases abruptly, due to a step reduction in the integrator windup limit. As shown in FIG. 7B, the dose error drops to about −2% shortly after the intervention, and the positive dose error is limited to 0.7% (around the point labeled 707). In this example simulation, an overdose fault was prevented and an overdose fault did not occur. However, although the process 400 may be used to mitigate or eliminate underdose faults, an underdose fault did occur in the simulation discussed with respect to FIGS. 7A-7G. As discussed above, the underdose fault may be addressed via further processing of the wafer.

These and other implementations are within the scope of the claims. For example, although some of the examples discussed above relate to controlling an optical source that provides light to an EUV light source, the power controller 255 may be used with any type of light source and any type of lithography system. For example, the power controller 255 may be used to control a light source that is part of a DUV lithography system.

The aspects and implementations can be further described using the following clauses:
1. A control apparatus comprising:
a power controller configured to control an amount of energy in an exposure beam; and
a tracking module configured to:
determine an amount of accumulated energy of a region that moves through the exposure beam while the region is in the exposure beam;
predict whether the accumulated energy of the region will exceed a dose limit prior to leaving the exposure beam; and
if the accumulated energy of the region is predicted to exceed the dose limit, provide a control input to the power controller.
2. The control apparatus of clause 1, wherein providing the control input to the power controller reduces the amount of energy in the exposure beam.
3. The control apparatus of clause 1, wherein the power controller comprises a proportional-integral controller, and the control input comprises an input of the integrator.
4. The control apparatus of clause 3, wherein the input of the integrator comprises an energy target and a control limit.
5. The control apparatus of clause 4, wherein, when provided to the power controller, the control limit reduces an amount of integral windup associated with the power controller.
6. The control apparatus of clause 1, wherein the power controller controls the amount of energy in the exposure beam based on an energy target; and
the control input comprises an energy target, and, when the control input is provided to the power controller, the energy target is reduced.
7. The control apparatus of clause 6, wherein the power controller controls the amount of energy in the exposure beam based on a proportional-integral controller;
and
the control input further comprises a control limit, and, when the control limit is provided to the power controller, an amount of integral windup associated with the power controller is reduced.
8. The control apparatus of clause 7, wherein, when the control input is provided to the power controller, the integrator gain is set to zero.
9. The control apparatus of clause 1, wherein the region is a first region, and the tracking module is further configured to:
determine an amount of accumulated energy of a second region that moves through the exposure beam while the second region is in the exposure beam, the second region being spatially distinct from the first region;
predict whether the accumulated energy of the second region will exceed the dose limit prior to leaving the exposure beam; and
if the accumulated energy of one or more of the first region and the second region is predicted to exceed the dose limit, provide a control input to the power controller.
10. The control apparatus of clause 1, wherein, the region moves through the exposure beam along a path from a first location at a first side of the exposure beam to a second location at a second side of the exposure beam, and to determine the amount of accumulated energy of the region while the region is in the exposure beam, the tracking module is configured to:
determine an amount of energy received at each location between the first location and a current location, the current location being on the path; and
determine the accumulated energy of the region by summing all of the determined amounts of energy.
11. The control apparatus of clause 10, wherein, to determine the amount of energy accumulated at a particular location on the path, the tracking module is configured to:
determine, for the particular location, a weighting factor based on a slit function that defines an energy distribution in the exposure beam; and
determine the energy received at the particular location based on the weighting factor and a measured amount of energy.
12. The control apparatus of clause 11, wherein the measured amount of energy is an amount of extreme ultraviolet (EUV) light provided to a lithography apparatus that forms the exposure beam.
13. The control apparatus of clause 1, wherein the region moves through the exposure beam along a path from a first location at a first side of the exposure beam to a second location at a second side of the exposure beam, and to predict whether the accumulated energy of the region will exceed a dose limit prior to leaving the exposure beam, the tracking module is configured to:
determine if the accumulated energy of the region will exceed the dose limit if the region receives a target amount of energy at each remaining location on the path.
14. The control apparatus of clause 13, wherein the target amount of energy varies over time such that the target amount of energy at each remaining location on the path is not constant.
15. The control apparatus of clause 14, wherein the target amount of energy at each remaining location is determined based on an initial target energy and a weighting function that varies with the location.
16. The control apparatus of clause 15, wherein the accumulated energy is determined based on the determined target amount of energy at each remaining location and a predefined gain factor.
17. The control apparatus of clause 16, wherein reducing the predefined gain factor reduces the determined amount of accumulated energy such that it is less likely that the accumulated energy will be predicted to exceed the dose limit, and increasing the predefined gain factor increases the determined amount of accumulated energy such that it is more likely that the accumulated energy will be predicted to exceed the dose limit.
18. The control apparatus of clause 1, wherein the dose limit is a range of values, and the accumulated energy of the region is predicted to exceed the dose limit if the accumulated energy is outside of the range of values.
19. The control apparatus of clause 1, wherein the power controller is coupled to a light source that emits pulses of light, the exposure beam is formed based on the pulses of light, and the control input controls an energy of pulses of light emitted by the light source to thereby control the amount of energy in the exposure beam.
20. The control apparatus of clause 19, wherein the exposure beam is formed from extreme ultraviolet (EUV) light emitted by a plasma, wherein the plasma is generated by an interaction between the pulses of light emitted by the light source and a target material.
21. A system comprising:
an optical source configured to provide light to a lithography apparatus to form an exposure beam in the lithography apparatus; and
a control apparatus comprising:
a power controller configured to control an amount of energy emitted by the optical source; and
a tracking module configured to:
determine an amount of accumulated energy of a region that moves through the exposure beam while the region is in the exposure beam;
predict whether the accumulated energy of the region will exceed a dose limit prior to leaving the exposure beam; and
if the accumulated energy of the region is predicted to exceed the dose limit, provide a control input to the power controller.
22. The system of clause 21, wherein the optical source comprises an extreme ultraviolet (EUV) light source.
23. The system of clause 22, wherein the power controller is configured to control the amount of energy emitted by the optical source by controlling a pulsed light source that provides pulses of light to a plasma formation region of the EUV light source.
24. The system of clause 23, wherein the power controller is configured to control the amount of energy in the pulses of light provided to the plasma formation region of the EUV light source.
25. The system of clause 24, wherein the optical source further comprises a pulsed light source that provides the pulses of light to a plasma formation region in the EUV light source.
26. The system of clause 25, wherein the optical source comprises a carbon dioxide laser.
27. The system of clause 25, wherein the power controller is further configured to control when the pulses are emitted from the pulsed light source.
28. The system of clause 21, wherein the region is a portion of a substrate that is configured to be received in the lithography apparatus.
29. The system of clause 21, further comprising the lithography apparatus.

The above-described implementations and other implementations are within the scope of the following claims.

1. A control apparatus comprising:
a power controller configured to control an amount of energy in an exposure beam; and
a tracking module configured to:
determine an amount of accumulated energy of a region that moves through the exposure beam while the region is in the exposure beam;
predict whether the accumulated energy of the region will exceed a dose limit prior to leaving the exposure beam; and
if the accumulated energy of the region is predicted to exceed the dose limit, provide a control input to the power controller.

2. The control apparatus of claim 1, wherein providing the control input to the power controller reduces the amount of energy in the exposure beam.

3. The control apparatus of claim 1, wherein the power controller comprises a proportional-integral controller, and the control input comprises an input of the integrator.

4. The control apparatus of claim 3, wherein the input of the integrator comprises an energy target and a control limit.

5. The control apparatus of claim 4, wherein, when provided to the power controller, the control limit reduces an amount of integral windup associated with the power controller.

6. The control apparatus of claim 1, wherein the power controller controls the amount of energy in the exposure beam based on an energy target; and
the control input comprises an energy target, and, when the control input is provided to the power controller, the energy target is reduced.

7. The control apparatus of claim 6, wherein the power controller controls the amount of energy in the exposure beam based on a proportional-integral controller;
and
the control input further comprises a control limit, and, when the control limit is provided to the power controller, an amount of integral windup associated with the power controller is reduced.

8. The control apparatus of claim 7, wherein, when the control input is provided to the power controller, the integrator gain is set to zero.

9. The control apparatus of claim 1, wherein the region is a first region, and the tracking module is further configured to:
determine an amount of accumulated energy of a second region that moves through the exposure beam while the second region is in the exposure beam, the second region being spatially distinct from the first region;
predict whether the accumulated energy of the second region will exceed the dose limit prior to leaving the exposure beam; and
if the accumulated energy of one or more of the first region and the second region is predicted to exceed the dose limit, provide a control input to the power controller.

10. The control apparatus of claim 1, wherein, the region moves through the exposure beam along a path from a first location at a first side of the exposure beam to a second location at a second side of the exposure beam, and to determine the amount of accumulated energy of the region while the region is in the exposure beam, the tracking module is configured to:
determine an amount of energy received at each location between the first location and a current location, the current location being on the path; and
determine the accumulated energy of the region by summing all of the determined amounts of energy.

11. The control apparatus of claim 10, wherein, to determine the amount of energy accumulated at a particular location on the path, the tracking module is configured to:
determine, for the particular location, a weighting factor based on a slit function that defines an energy distribution in the exposure beam; and
determine the energy received at the particular location based on the weighting factor and a measured amount of energy, wherein the measured amount of energy is an amount of extreme ultraviolet (EUV) light provided to a lithography apparatus that forms the exposure beam.

12. (canceled)

13. The control apparatus of claim 1, wherein the region moves through the exposure beam along a path from a first location at a first side of the exposure beam to a second location at a second side of the exposure beam, and to predict whether the accumulated energy of the region will exceed a dose limit prior to leaving the exposure beam, the tracking module is configured to:
determine if the accumulated energy of the region will exceed the dose limit if the region receives a target amount of energy at each remaining location on the path.

14. The control apparatus of claim 13, wherein the target amount of energy varies over time such that the target amount of energy at each remaining location on the path is not constant.

15. The control apparatus of claim 14, wherein the target amount of energy at each remaining location is determined based on an initial target energy and a weighting function that varies with the location.

16. The control apparatus of claim 15, wherein the accumulated energy is determined based on the determined target amount of energy at each remaining location and a predefined gain factor.

17. The control apparatus of claim 16, wherein reducing the predefined gain factor reduces the determined amount of accumulated energy such that it is less likely that the accumulated energy will be predicted to exceed the dose limit, and increasing the predefined gain factor increases the determined amount of accumulated energy such that it is more likely that the accumulated energy will be predicted to exceed the dose limit.

18. The control apparatus of claim 1, wherein the dose limit is a range of values, and the accumulated energy of the region is predicted to exceed the dose limit if the accumulated energy is outside of the range of values.

19. The control apparatus of claim 1, wherein the power controller is coupled to a light source that emits pulses of light, the exposure beam is formed based on the pulses of light, and the control input controls an energy of pulses of light emitted by the light source to thereby control the amount of energy in the exposure beam.

20. (canceled)

21. A system comprising:
an optical source configured to provide light to a lithography apparatus to form an exposure beam in the lithography apparatus; and
a control apparatus comprising:
a power controller configured to control an amount of energy emitted by the optical source; and
a tracking module configured to:
determine an amount of accumulated energy of a region that moves through the exposure beam while the region is in the exposure beam;
predict whether the accumulated energy of the region will exceed a dose limit prior to leaving the exposure beam; and
if the accumulated energy of the region is predicted to exceed the dose limit, provide a control input to the power controller.

22. The system of claim 21, wherein the optical source comprises an extreme ultraviolet (EUV) light source.

23. The system of claim 22, wherein the power controller is configured to control the amount of energy emitted by the optical source by controlling a pulsed light source that provides pulses of light to a plasma formation region of the EUV light source, and wherein the power controller is configured to control the amount of energy in the pulses of light provided to the plasma formation region of the EUV light source.

24. (canceled)

25. The system of claim 23, wherein the optical source further comprises a pulsed light source that provides the pulses of light to a plasma formation region in the EUV light source, and wherein the power controller is further configured to control when the pulses are emitted from the pulsed light source.

26-29. (canceled)
